(19) United States
(12) Patent Application Publication
(10) Pub. No.: US 2014/0143620 A1
(43) Pub. Date: May 22, 2014

(54) SEMICONDUCTOR APPARATUS AND TEST METHOD THEREOF

(71) Applicant: SK HYNIX INC., Icheon-si Gyeonggi-do (KR)

(72) Inventor: Byung Deuk JEON, Icheon-si Gyeonggi-do (KR)

(21) Appl. No.: 13/846,132

(22) Filed: Mar. 18, 2013

(30) Foreign Application Priority Data
Nov. 19, 2012 (KR) 10-2012-0130883

(51) Int. Cl. G01R 31/317

(52) U.S. Cl. CPC G01R 31/31712
USPC 714/724

(57) ABSTRACT

A semiconductor apparatus includes a data output unit and a test output unit. The data output unit outputs a plurality of data, through a plurality of data lines, to a plurality of input/output pads. The test output unit receives one of the plurality of data and a plurality of output data, which is output to the plurality of input/output pads, and outputs the received data to a probe pad in a probe test mode.

### CROSS-REFERENCE TO RELATED APPLICATION

The present application claims priority under 35 U.S.C. §119(a) to Korean application number 10-2012-0130883 filed on Nov. 19, 2012 in the Korean Intellectual Property Office, which is incorporated herein by reference in its entirety.

### BACKGROUND

1. Technical Field

Various embodiments generally relate to a semiconductor apparatus and a test method thereof, and more particularly, to a semiconductor test apparatus and method for testing a data output path test of a semiconductor apparatus.

2. Related Art

In fabricating a semiconductor apparatus, a test process is performed to check whether the semiconductor apparatus normally operates in order to improve production efficiency. The test process for the semiconductor apparatus is performed by applying an electrical signal to a pad of the semiconductor apparatus and checking whether output data is normal.

Recently, a semiconductor apparatus, in which semiconductor chips are stacked using through-silicon vias (TSVs), has been developed. Such a semiconductor apparatus, for example, employs a bump pad structure for an input/output pad. That is, in a semiconductor package, a plurality of chips are coupled to one another through TSVs, and a bump pad transfers a signal among the TSVs of the chips. However, it is generally known that the bump pad has a low loading ability for outputting data. By extension, an output driver for outputting data to the bump pad also has a driving ability lower than that of a general semiconductor apparatus using a wire as a signal transferring member.

Therefore, it is hard to perform the probe test using the output driver with the bump pad, because of the low data loading ability of the bump pad. In this regard, a probe test circuit independent from the output driver with the bump pad is desired.

Referring to FIG. 1, a general semiconductor apparatus includes a data output unit 1, an input/output pad 2, a probe test output unit 3, and a probe pad 4.

In a read operation, data stored in a memory cell (not illustrated) is transmitted through a data line GIO. The data output unit 1 receives data DI and outputs output data DO to the input/output pad 2. The input/output pad 2 may be set to have a low data output load, and for example, may have a bump pad structure.

The probe pad 4 is provided in order to perform a probe test to test whether memory cells in the semiconductor apparatus are normally manufactured. The probe test output unit 3 receives the data DI and outputs probe test data PDO when a test mode signal TM is activated. The probe test output unit 3 is set to have a data driving ability higher than that of the data output unit 1. The probe test data PDO may be output through the probe pad 4. The probe test data PDO output by the probe pad 4 may be provided to a probe test apparatus which is separate from the semiconductor apparatus.

The probe test output unit 3 and the probe pad 4 for the probe test are provided separately from the data output unit 1. However, areas for failure in the semiconductor apparatus may exist in various parts of the semiconductor apparatus as well as in the memory cells. For example, such areas may exist in a data output path for outputting data, that is, in an output driver and circuits related with the output driver. In this regard, it is necessary to provide a scheme for screening potential areas for failure in advance and improving the production efficiency of the semiconductor apparatus.

### SUMMARY

In an embodiment, a semiconductor apparatus includes: a test output unit configured to receive a plurality of output data provided to a plurality of input/output pads and transmit the received data to a probe pad in a data output path test mode.

In an embodiment, a semiconductor apparatus includes: a data output unit configured to output a plurality of data, through a plurality of data lines, to a plurality of input/output pads; and a test output unit configured to receive one of the plurality of data and the plurality of output data, which is output to the plurality of input/output pads, and to output the received data to a probe pad in a test mode.

In an embodiment, a method for testing a semiconductor apparatus includes the steps of: simultaneously writing a plurality of data having substantially same levels in a plurality of memory cells; reading the plurality of data written in the plurality of memory cells and outputting the read data to a plurality of input/output pads; and outputting the plurality of output data, which is output to the plurality of input/output pads, to a probe pad.

In an embodiment, a semiconductor apparatus for probe testing fails of data provided from data input/output lines and an output path of the data though an output pad, includes a test output unit configured to selectively receive the data provided from the data input/output lines and the data provided from the output pad in response to the test selection mode signal during a test mode, to is process the receive data, and to output the processed data as a probing test data.

### BRIEF DESCRIPTION OF THE DRAWINGS

Features, aspects, and embodiments are described in conjunction with the attached drawings, in which:

FIG. 1 is a block diagram schematically illustrating a semiconductor apparatus having a general bump pad structure;

FIG. 2 is a block diagram schematically illustrating a semiconductor apparatus according to an embodiment of the present invention;

FIG. 3 is a block diagram illustrating a detailed example of the test output unit of FIG. 2;

FIG. 4 is a circuit diagram illustrating a detailed example of the compression section of FIG. 3; and

FIG. 5 is a flowchart illustrating a test method of a semiconductor apparatus according to an embodiment of the present invention.

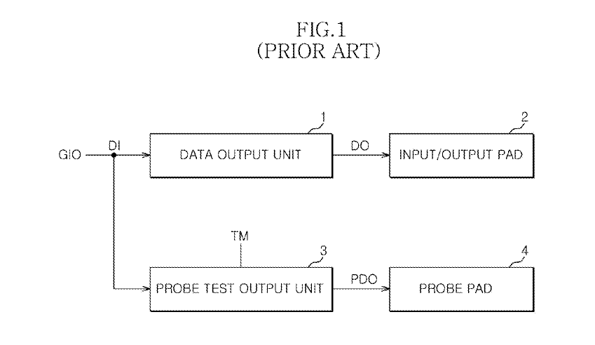

### DETAILED DESCRIPTION

Hereinafter, a semiconductor apparatus and a test method thereof according to various embodiments of the present invention will be described in detail with reference to the accompanying drawings.

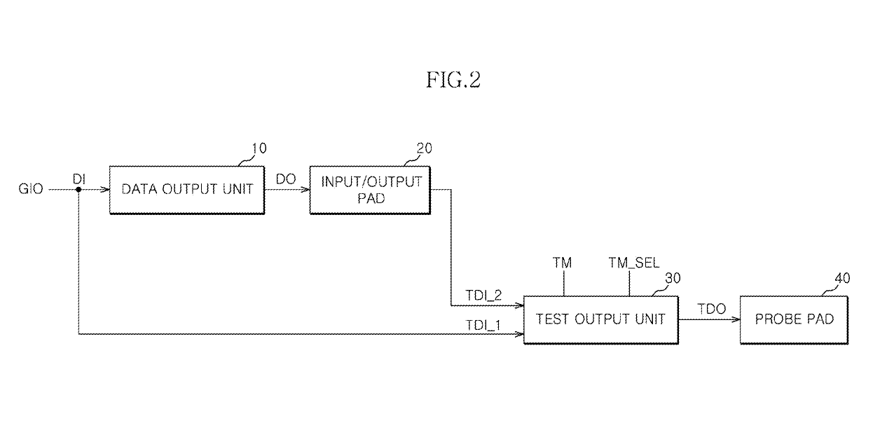

Referring to FIG. 2, a semiconductor apparatus having a data output path for outputting the data includes a data output unit 10, an input/output pad 20, a test output unit 30, and a probe pad 40.

The data output unit 10 may be configured to receive data DI transmitted from a data line GIO and generate output data DO. In detail, the data output unit 10 may include a circuit such as a flip-flop for outputting data in synchronization with a clock or an output driver for driving data.

The input/output pad 20 may be configured to output the output data DO to other circuit blocks which are separate from the semiconductor apparatus or to receive a signal from one of the other circuit blocks. In an embodiment, a bump pad may be used as the input/output pad 20. Since the bump pad has a low data output loading ability, a driving ability of the data output unit 10 may be set to low by extension.

The test output unit 30 may be configured to be activated in response to a test mode signal TM. The test output unit 30 may be configured to selectively receive the data DI as first test input data TDI_{—}1 or the output data DO as second test input data TDI_{—}2 in response to a test selection signal TM_SEL. That is, in the state in which the test output unit 30 has been activated, when a test selection signal TM_SEL having a first level is applied, the test output unit 30 may receive the data DI and output the data DI to the probe pad 40 as test data TDO. When a test selection signal TM_SEL having a second level is applied, the test output unit 30 may receive the output data DO and output the output data DO to the probe pad 40 as the test data TDO.

The probe pad 40 may be configured to output the test data TDO to other circuits which are separate from the semiconductor apparatus, such as a probe test apparatus. The probe pad 40 may be formed to include a higher data output loading ability than that of the input/output pad 20. Since the probe pad 40 may be formed to include relatively high data output loading ability, the driving ability of the test output unit 30 may be set higher than that of the data output unit 10 by extension.

The operation of the semiconductor apparatus according to an embodiment will be described below.

In a normal operation, when the semiconductor apparatus performs a data output operation such as a data read operation, data stored in the memory cell may be transmitted to the data output unit 10 through the data line GIO. The data output unit 10 may receive the- data DI transmitted from the memory cell and may output the data DI to the input/output pad 20 as the output data DO. Since during the normal operation the test mode signal TM is deactivated, the test output unit 30 may enter a deactivated state, although the data DI may be provided to the test output unit 30.

In a test mode, when the semiconductor apparatus performs the data output operation such as the data read operation, data stored in the memory cell may be transmitted to the data output unit 10 through the data line GIO. The data output unit 10 may receive the data DI transmitted from the memory cell and may output the data DI to the input/output pad 20 as the output data DO.

Since during the test mode the test mode signal TM is activated, the test output unit 30 may enter an activated state. An operation mode of the test output unit 30 may be determined in response to the test selection signal TM_SEL. For example, when the test selection signal TM_SEL having a first level is applied, the test output unit 30 may operate in a first mode. In the first mode, the test output unit 30 may receive the first test input data TDI_{—}1, that is, the data DI, and may output the first test input data TDO_{—}1 as the test data TDO. When the test selection signal TM_SEL having a second level is applied, the test output unit 30 may operate in a second mode. In the second mode, the test output unit 30 may receive the second test input data TDI_{—}2, that is, the output data DO provided from the input/output pad 20, and may output the second test input data TDI_{—}2 as the test data TDO.

The semiconductor apparatus according to an embodiment may include the test output unit 30 which may provide the data DI transmitted to the data line GIO or the output data DO output to the input/output pad 20, to the probe pad 40, thereby performing the probe test. In the first mode, the semiconductor apparatus may perform a probe test for the data of the memory cell loaded on the data line GIO, thereby verifying fail of a memory cell. In the second mode, the semiconductor apparatus may perform a probe test for the data output to the input/output pad 20 through a data output path of the data output unit 10, thereby verifying fail of the data output path.

For example, when the test data TDO has a normal first preset value in the first mode, it may represent that no fail exists in the memory cell. However, when the test data TDO is beyond the normal first preset value in the first mode, it is possible to recognize that a fail exists in the memory cell.

When the test data TDO has a normal second preset value in the second mode, it may represent that no fail exists in the data output path. However, when the test data TDO is beyond the normal second present value in the second mode, it is possible to recognize that a fail exists in the data output path.

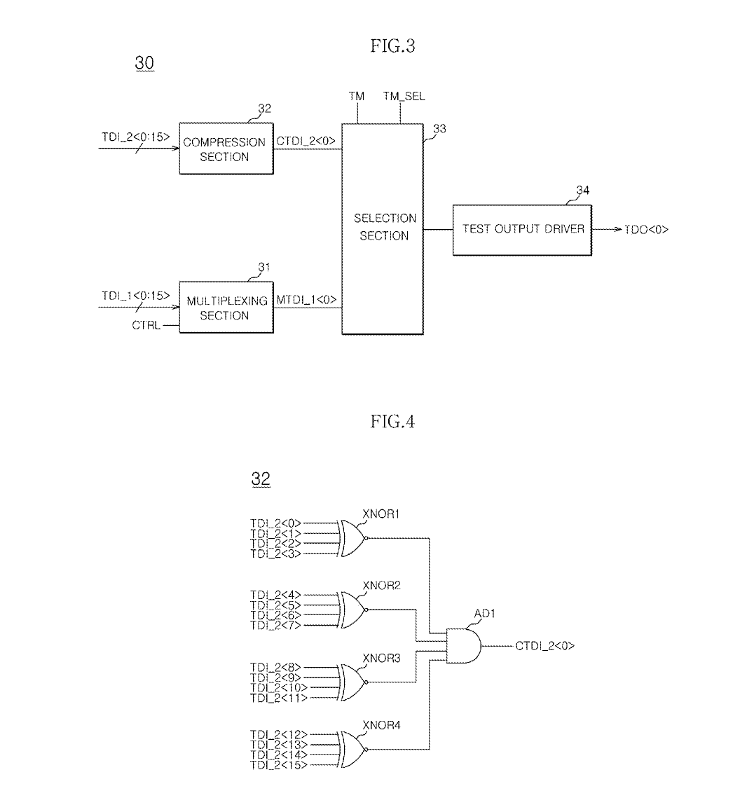

As shown in FIG. 3, the test output unit 30 may include a multiplexing section 31, a compression section 32, a selection section 33, and a test output driver 34.

The multiplexing section 31 may be configured to receive a plurality of first test input data TDI_{—}1<0:15> and output one of the plurality of the first test input data TDI_{—}1<0:15> as selection transmission data MTDI_{—}1<0> in response to a control signal CTRL. The data line GIO may include a plurality of lines, and the plurality of first test input data TDI_{—}1<0:15> may correspond to a plurality of data DI transmitted through the plurality of data lines GIO. The control signal CTRL may be applied in order to select one of the plurality of first test input data TDI_{—}1<0:15>. The plurality of first test input data TDI_{—}1<0:15> may be sequentially selected according to level changes of the control signal CTRL. The semiconductor apparatus according to an embodiment may not need a plurality of probe pads corresponding to numbers of the plurality of first input data TDI_{—}1<0:15>, since one of the plurality of first input data TDI_{—}1<0:15> may be selected through the multiplexing section 31. Thus, the semiconductor apparatus can perform a test for all data through less probe pads 40 compared to the number of input/output pads 20.

The compression section 32 may be configured to compress a plurality of second test input data TDI_{—}2<0:15> and output compression data CTDI_{—}2<0>. A compression scheme may be used to simultaneously verify a plurality of data, and may be set in such a manner that when all the plurality of second test input data TDI_{—}2<0:15> has substantially the same level, compression data CTDI_{—}2<0> having a first level is generated, and when the plurality of second test input data TDI_{—}2<0:15> does not have substantially the same level, compression data CTDI_{—}2<0> having a second level is generated. That is, if all of the second test input data TDI_{—}2<0:15> have substantially the same level, there is no fail in the semiconductor apparatus, and the compression section 32 may output the compression data CTDI_{—}2<0> having a first level. If at least one second test input data TDI_{—}2<0:15> have different level, there is a fail generated in the data output path of the semiconductor apparatus, and the compression section 32 may output the compression data CTDI_{—}2<0> having a second level.

The selection section 33 may be configured to be activated in response to the test mode signal TM, receive the selection is transmission data MTDI_{—}1<0> and the compression data CTDI_{—}2<0>, and select one of the selection transmission data MTDI_{—}1<0> or the compression data CTDI_{—}2<0> in response to the test selection signal TM_SEL. That is, in the state in which the selection section 33 has been activated, when a test selection signal TM_SEL having a first level is applied, the selection section 33 may select and output the selection transmission data MTDI_{—}1<0>. When a test selection signal TM_SEL having a second level is applied, the selection section 33 may receive and output the compression data CTDI_{—}2<0>.

The test output driver 34 may be configured to receive the output signal of the selection section 33, drive the output signal of the selection section 33, and output the output signal as test data TDO<0>.

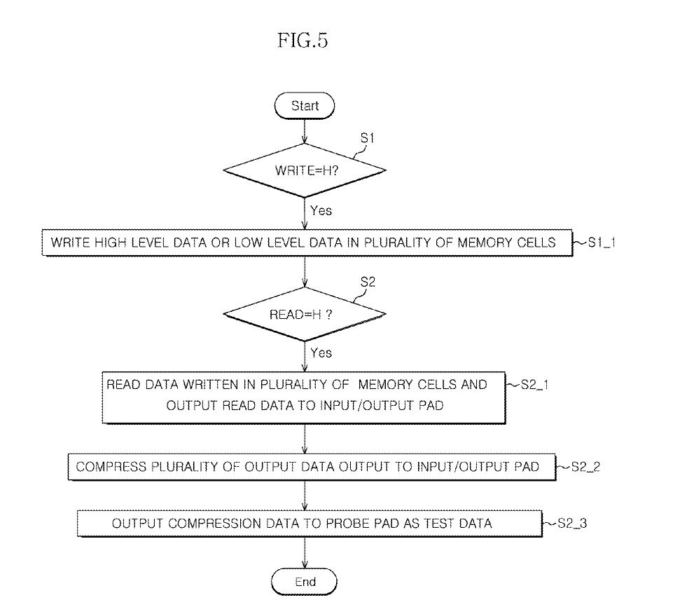

Referring to FIG. 4, the compression section 32 may include first to fourth exclusive NOR gates XNOR1 to XNOR4 and an AND gate AD1.

The exclusive NOR gates XNOR1 to XNOR4 may be configured to receive a predetermined number of second test input data TDI_{—}2 <0:15> and perform an XNOR operation on the received data, respectively. The exclusive NOR gate may generate an output signal having a high level when all the levels of a plurality of input values are substantially equal to one another, and may generate an output signal having a low level when the levels of the plurality of input values are different from one another. For example, each of the exclusive NOR gates XNOR1 to XNOR4 is a 4-input element: the first exclusive NOR gate XNOR1 performs an XNOR operation on TDI_{—}2<0> to TDI_{—}2<3>, the second exclusive NOR gate XNOR2 performs an XNOR operation on TDI_{—}2<4> to TDI_{—}2<7>, the third exclusive NOR gate XNOR3 performs an XNOR operation on TDI_{—}2<8> to TDI_{—}2<11>, and the fourth exclusive NOR gate XNOR4 performs an XNOR operation on TDI_{—}2<12> to TDI_{—}2<15>.

The AND gate AD1 may be configured to receive the output of the first to fourth exclusive NOR gates XNOR1 to XNOR4, perform an AND operation on the received output, and output the compression data CTDI_{—}2<0>. When all the output values of the first to fourth exclusive NOR gates XNOR1 to XNOR4 have a high level, the AND gate AD1 generates may generate the compression data CTDI_{—}2<0> having a high level. Even when one of the output values of the first to fourth exclusive NOR gates XNOR1 to XNOR4 has a low level, the AND gate AD1 may generate the compression data CTDI_{—}2<0> having a low level.

Referring to FIG. 5, in a test mode, data may be simultaneously written in all of a plurality of memory cells of the semiconductor apparatus. That is, when a write command WRITE is activated (S1), data having high level or low level are written in a plurality of memory cells of the semiconductor apparatus. (S1_{—}1).

Subsequently, a reading operation of the semiconductor apparatus may be performed. That is, when a read command READ is activated (S2), the data written in the plurality of memory cells may be output to the input/output pads through the data output circuit (S2_{—}1). The data of the input/output pad may be transmitted to the probe pad through the test output unit in order to check for fail data of the data output path. However, since the number of the probe pads may be limited due to design efficiency, a step of compressing a plurality of data output to the input/output pads may be added (S2_{—}2). As described above, compression may be performed in such a manner where compression data having a first level is generated when all the levels of the plurality of data are substantially equal to one another, and compression data having a second level is generated when the levels of the plurality of data are different from one another. The compression data may be output to the probe pads as test data (S2_{—}3) and the test data may be probed by a probe test apparatus. Thus, it is possible to perform a probe test for the data output path.

According to an embodiment, it is possible to verify a fail of the data output path of the semiconductor memory apparatus as well as a fail of the memory cell. It will be understood to those skilled in the art that the absence of a fail of a memory cell may be verified through the memory cell fail test, and when the data output path test is performed and thus the presence of fail has been checked through the test data, it is possible to recognize that fail exists on the data output path including the output driver and the output circuit.

While certain embodiments have been described above, it will be understood to those skilled in the art that the embodiments described are by way of example only. Accordingly, the is semiconductor apparatus and the test method thereof described herein should not be limited based on the described embodiments. Rather, the semiconductor apparatus and the test method thereof described herein should only be limited in light of the claims that follow when taken in conjunction with the above description and accompanying drawings.

What is claimed is:

1. A semiconductor apparatus comprising:
a test output unit configured to receive a plurality of output data provided from a plurality of input/output pads and transmit the received output data to a probe pad in a test mode.

2. The semiconductor apparatus according to claim 1, wherein the test output unit is configured to receive the plurality of output data and to output a compression data obtained by compressing the plurality of output data to the probe pad.

3. The semiconductor apparatus according to claim 2, wherein the compression data includes a first level when all levels of is the plurality of output data are substantially equal to one another and a second level when the levels of the plurality of output data are different from one another.

4. A semiconductor apparatus comprising:
a data output unit configured to output a plurality of data, which is transmitted through a plurality of data lines, to a plurality of input/output pads; and
a test output unit configured to receive one of the plurality of data and a plurality of output data provided from the plurality of input/output pads, and to output a received data to a probe pad in a test mode.

5. The semiconductor apparatus according to claim 4, wherein the test output unit is configured to be activated in response to a test mode signal.

6. The semiconductor apparatus according to claim 5, wherein the test output unit is configured to receive the plurality of data and output the plurality of data to the probe pad in a first mode, and to receive the plurality of output data and output the plurality of output data to the probe pad in a second mode in response to a test selection signal.

7. The semiconductor apparatus according to claim 4, is wherein the test output unit comprises:
a multiplexing section configured to output one of the plurality of data, which is transmitted through the plurality of data lines, as selection transmission data in response to a control signal;
a compression section configured to compress the plurality of output data provided from the plurality of input/output pads, and to output a compression data;
a selection section configured to output one of the selection transmission data and the compression data in response to a test selection signal when an activated test mode signal is applied; and
a test output driver configured to provide output of the selection section to the probe pad as a test data.

8. The semiconductor apparatus according to claim 7, wherein the compression section is configured to generate compression data having a first level when all levels of the plurality of output data are substantially equal to one another, and to generate compression data having a second level when the levels of the plurality of output data are different from one another.

9. The semiconductor apparatus according to claim 7, wherein the selection section is configured to select and output the selection transmission data in a first mode, and to select and output the compression data in a second mode in response to the test selection signal.

10. A method for testing a semiconductor apparatus, comprising the steps of:
simultaneously writing a plurality of data having substantially a same level in a plurality of memory cells;
reading the plurality of data written in the plurality of memory cells and outputting the read data to a plurality of input/output pads; and
outputting the plurality of output data, which is output to the plurality of input/output pads, to a probe pad.

11. The method according to claim 10, wherein the step of outputting the output data to the probe pad comprises the steps of:
compressing the plurality of output data which is output to the plurality of input/output pads, and generating a compression data; and
outputting the compression data to the probe pad as a test data.

12. The method according to claim 11, wherein the step of generating the compression data comprises the steps of:
generating a first level when all levels of the plurality of output data are substantially equal to one another; and
generating a second level when the levels of the plurality of output data are different from one another.
